(19) United States
(12) Patent Application Publication
(10) Pub. No.: US 2024/0164191 A1
(43) Pub. Date: May 16, 2024

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Jiajia SUN, Wuhan (CN)

(21) Appl. No.: 18/288,868

(22) PCT Filed: Jun. 29, 2023
(86) PCT No.: PCT/CN2023/103910

§ 371 Date: Oct. 30, 2023

(30) Foreign Application Priority Data
Nov. 14, 2022 (CN) 202211425569.3

(51) Int. Cl. H10K 59/80; H10K 59/122; H10K 59/35

(52) U.S. Cl. CPC H10K 59/879; H10K 59/122; H10K 59/353; H10K 59/8791; H10K 59/40

(57) ABSTRACT

A display panel and a display device are provided, and include a light-emitting layer and an optical functional layer that are stacked; the optical functional layer includes a first microlens structure and a second microlens structure; the light-emitting layer includes a first light-emitting sub-pixel and a second light-emitting sub-pixel; there is a first interval in a first direction is between a center point of the first microlens structure and a center point of the first light-emitting sub-pixel, there is a second interval in a second direction between a center point of the second microlens structure and a center point of the second light-emitting sub-pixel, and the first direction is different from the second direction.

### TECHNICAL FIELD

The present application relates to the field of display, and more particularly, to a display panel and a display device.

### BACKGROUND

An Organic Light-Emitting Diode (OLED) display device has been regarded as a next generation of new display technology because of its light weight, wide viewing angle, fast response time, low temperature resistance, high luminous efficiency, and the like.

In order to reduce power consumption of an OLED display panel, a researcher in the art, based on a geometric optical principle, proposes a technical solution in which a Micro Lens Pattern (MLP) is provided in an OLED screen body, and divergent light emitted from the OLED screen body is converged directly above the screen body, thereby improving efficiency of the OLED screen body and reducing power consumption of the OLED panel. However, in the technical solution, the MLP structure needs to be one-to-one corresponding to the pixel, and the existence of the alignment deviation brings the problem of poor viewing angle symmetry to the OLED display panel.

### SUMMARY

The present application provides a display panel and a display device, so as to improve the viewing angle symmetry of the existing OLED display panel.

In a first aspect, the present application provides a display panel including:
a substrate;
a light-emitting layer disposed on one side of the substrate, the light-emitting layer including a plurality of light-emitting sub-pixels;
an optical functional layer disposed on a side of the light-emitting layer away from the substrate, the optical functional layer including a plurality of microlens structures that are arranged in one-to-one correspondence with the light-emitting sub-pixels;
in which the plurality of microlens structures include a plurality of repeating units arranged periodically; each of the repeating units includes a first microlens structure and a second microlens structure; the plurality of light-emitting sub-pixels include a first light-emitting sub-pixel corresponding to the first microlens structure and a second light-emitting sub-pixel corresponding to the second microlens structure;
there is a first interval in a first direction is between a center point of the first microlens structure and a center point of the first light-emitting sub-pixel, there is a second interval in a second direction between the center point of the second microlens structure and a center point of the second light-emitting sub-pixel, and the first direction is different from the second direction.

In the display panel provided by the present application, the first direction is opposite to the second direction;

the first interval and the second interval are the same.

In the display panel provided by the present application, each of the repeating units further includes a third microlens structure; the plurality of light-emitting sub-pixels further include a third light-emitting sub-pixel corresponding to the third microlens structure;

there is a third interval in a third direction between a center point of the third microlens structure and a center point of the third light-emitting sub-pixel, and the first direction, the second direction, and the third direction are different.

In the display panel provided by the present application, the first direction, the second direction, and the third direction are arranged at intervals of 120 degrees in sequence;

the first interval, the second interval, and the third interval are the same.

In the display panel provided by the present application, each of the repeating units further includes a fourth microlens structure; the plurality of light-emitting sub-pixels further include a fourth light-emitting sub-pixel corresponding to the fourth microlens structure;

there is a fourth interval in a fourth direction between a center point of the fourth microlens structure and a center point of the fourth light-emitting sub-pixel, and the first direction, the second direction, the third direction, and the fourth direction are different.

In the display panel provided by the present application, the first direction, the second direction, the third direction, and the fourth direction are arranged at intervals of 90 degrees in sequence;

the first interval, the second interval, the third interval, and the fourth interval are the same.

In the display panel provided by the present application, each of the microlens structures has a same shape as a corresponding one of the light-emitting sub-pixels, and the microlens structure has a same size as the corresponding one of the light-emitting sub-pixels.

In the display panel provided by the present application, the first interval and the second interval are less than or equal to 5 microns.

In the display panel provided by the present application, the plurality of light-emitting sub-pixels include a plurality of red light-emitting sub-pixels, a plurality of green light-emitting sub-pixels, and a plurality of blue light-emitting sub-pixels; and the first interval corresponding to any one of the red light-emitting sub-pixels, the first interval corresponding to any one of the green light-emitting sub-pixels, and the first interval corresponding to any one of the blue light-emitting sub-pixels are equal to each other.

In the display panel provided by the present application, the plurality of the light-emitting sub-pixels include red light-emitting sub-pixels, green light-emitting sub-pixels, and blue light-emitting sub-pixels; the first interval corresponding to any one of the red light-emitting sub-pixels is smaller than the first interval corresponding to any one of the green light-emitting sub-pixels and larger than the first interval corresponding to any one of the blue light-emitting sub-pixels.

In the display panel provided by the present application, the first interval corresponding to any one of the red light-emitting sub-pixel is greater than 1 micron and less than or equal to 3 microns, the first interval corresponding to any one of the blue light-emitting sub-pixels is greater than 0 microns and less than or equal to 2 microns, and the first interval corresponding to any one of the green light-emitting sub-pixels is greater than 2 microns and less than or equal to 5 microns.

In the display panel provided by the present application, the microlens structures each have a same shape as a corresponding one of the light-emitting sub-pixels, and a size of the microlens structure is greater than a size of the corresponding one of the light-emitting sub-pixels.

In the display panel provided by the present application, the display panel further includes:
a pixel definition layer disposed between the substrate and the light-emitting layer, and the pixel definition layer includes a plurality of first openings corresponding to the light-emitting sub-pixels;
the optical functional layer includes a first refractive index layer disposed on a side of the light-emitting layer which is away from the substrate, and a second refractive index layer disposed on a side of the first refractive index layer which is away from the substrate, the first refractive index layer includes a plurality of second openings corresponding to the microlens structures, and a refractive index of the first refractive index layer is smaller than a refractive index of the second refractive index layer.

In a second aspect, the present application further provides a display device including a display panel; the display panel including:
a substrate;
a light-emitting layer disposed on one side of the substrate, the light-emitting layer including a plurality of light-emitting sub-pixels;
an optical functional layer disposed on a side of the light-emitting layer away from the substrate, the optical functional layer including a plurality of microlens structures that are arranged in one-to-one correspondence with the light-emitting sub-pixels;
in which the plurality of microlens structures include a plurality of repeating units arranged periodically; each of the repeating units includes a first microlens structure and a second microlens structure; the plurality of light-emitting sub-pixels include a first light-emitting sub-pixel corresponding to the first microlens structure and a second light-emitting sub-pixel corresponding to the second microlens structure;
there is a first interval in a first direction is between a center point of the first microlens structure and a center point of the first light-emitting sub-pixel, there is a second interval in a second direction between the center point of the second microlens structure and a center point of the second light-emitting sub-pixel, and the first direction is different from the second direction.

In the display device provided by the present application, the first direction is opposite to the second direction;

the first interval and the second interval are the same.

In the display device provided by the present application, the repeating units each further include a third microlens structure; the plurality of light-emitting sub-pixels further include a third light-emitting sub-pixel corresponding to the third microlens structure;

there is a third interval in a third direction between a center point of the third microlens structure and a center point of the third light-emitting sub-pixel, and the first direction, the second direction, and the third direction are different.

In the display device provided by the present application, the first direction, the second direction, and the third direction are arranged at intervals of 120 degrees in sequence;

the first interval, the second interval, and the third interval are the same.

In the display device provided by the present application, the repeating units each further include a fourth microlens structure; the plurality of light-emitting sub-pixels further include a fourth light-emitting sub-pixel corresponding to the fourth microlens structure;

there is a fourth interval in a fourth direction between a center point of the fourth microlens structure and a center point of the fourth light-emitting sub-pixel, and the first direction, the second direction, the third direction, and the fourth direction are different.

In the display device provided by the present application, the first direction, the second direction, the third direction, and the fourth direction are arranged at intervals of 90 degrees in sequence;

the first interval, the second interval, the third interval, and the fourth interval are the same.

In the display device provided by the present application, the microlens structures each have a same shape as a corresponding one of the light-emitting sub-pixels, and the microlens structure has a same size as the corresponding one of the light-emitting sub-pixels.

### Beneficial Effect

Compared with the prior art, in the present application, each first microlens structure in the display panel is set to be offset with respect to a center point of the corresponding first light-emitting sub-pixel, each second microlens structure is set to be offset with respect to a center point of the corresponding second light-emitting sub-pixel, and the two offset directions are different, so that the problem that all the microlens structures in the display panel are offset in one direction with respect to the respective light-emitting sub-pixels is alleviated to a certain extent, and the problem of viewing angle symmetry of the display panel is alleviated.

### BRIEF DESCRIPTION OF THE DRAWINGS

FIG. 1 is a schematic view of plan structures of each of light-emitting sub-pixels with the same color and a corresponding one of the microlens structures in a display panel in an ideal state;

FIG. 2 is a schematic sectional view in a direction of AA′ in FIG. 1;

FIG. 3 is a schematic view of plan structures of each of light-emitting sub-pixels with the same color and a corresponding one of microlens structures in a display panel in the prior art;

FIG. 4 is a schematic sectional view in a direction of BB′ in FIG. 3;

FIG. 5 is a view showing a result of viewing angle symmetry of a display panel in the prior art;

FIG. 6 is a first schematic diagram of a plane superposition structure of each of light-emitting sub-pixels with the same color and a corresponding one of microlens structures in a display panel according to an embodiment of the present application;

FIG. 7 is a schematic diagram of a plan superposition structure of the microlens structures of FIG. 6 when occurring alignment deviation;

FIG. 8 is a second schematic diagram of a plane superposition structure of each of light-emitting sub-pixels with the same color and a corresponding one of microlens structures in a display panel according to an embodiment of the present application;

FIG. 9 is a schematic diagram of a plan superposition structure of the microlens structures of FIG. 8 when occurring alignment deviation;

FIG. 10 is a third schematic diagram of a plane superposition structure of each of light-emitting sub-pixels with the same color and a corresponding one of microlens structures in a display panel according to an embodiment of the present application;

FIG. 11 is a schematic diagram of a plan superposition structure of the microlens structures of FIG. 10 when occurring alignment deviation;

FIG. 12 is a schematic sectional view of a display panel according to an embodiment of the present application.

### DETAILED DESCRIPTION

The technical arrangements in the embodiments and/or examples of the present application will be clearly and completely described in combination with the specific embodiments of the present application, and it will be apparent that the embodiments and/or examples described below are merely a part of the embodiments and/or examples of the present application, rather than all the embodiments and/or examples. Based on the embodiments and/or examples in the present application, all other embodiments and/or examples obtained by a person of ordinary skill in the art without involving any inventive effort are within the scope of the present application.

The direction terms mentioned in the present application, such as [upper], [lower], [left], [right], [front], [rear], [inner], [outer], [side], and the like, are only directions with reference to the additional drawings. Thus, directional language is used to illustrate and understand the present application, and not to limit the present application. The terms “first,” “second,” and the like are used for descriptive purposes only and are not to be construed as indicating or implying their relative importance or implying the number of indicated technical features. Thus, the features defined by “first”, “second,” and the like can include one or more features explicitly or implicitly.

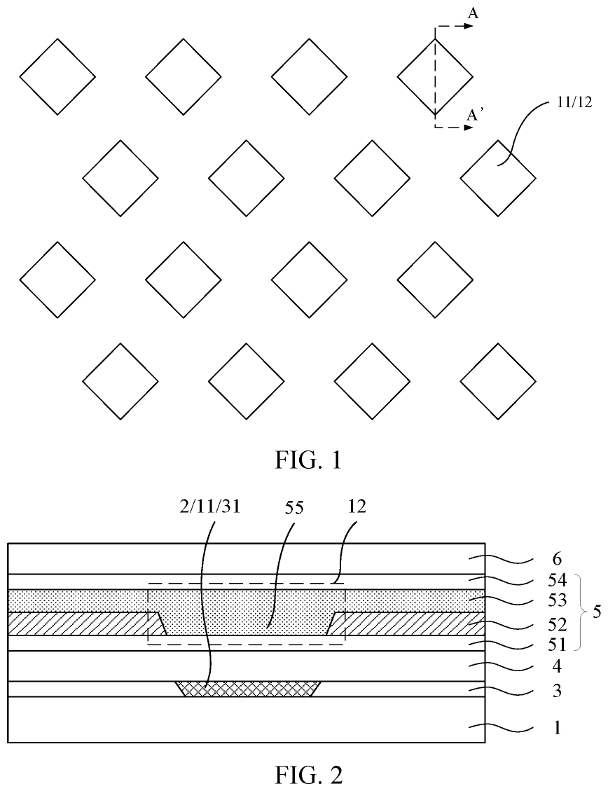

Referring to FIG. 1, is a schematic view of plan structures of each of light-emitting sub-pixels with the same color and a corresponding one of the microlens structures in a display panel in an ideal state. Specifically, FIG. 1 is a schematic view of plan structures of each of light-emitting sub-pixels with the same color and a corresponding one of the microlens structures in a pixel diamond arrangement manner. FIG. 2 is a schematic sectional view in a direction of AA′ of FIG. 1. Ideally, the display panel mainly includes a substrate 1, a light-emitting layer 2, a pixel definition layer 3, an encapsulation layer 4, an optical function layer 5, and a cover plate 6, which are stacked in sequence. The substrate 1 includes a thin film transistor circuit. The light-emitting layer 2 includes a plurality of light-emitting sub-pixels 11. The pixel definition layer 3 is disposed between the substrate 1 and the light-emitting layer 2. The pixel definition layer 3 includes a plurality of first openings 31 corresponding to the light-emitting sub-pixels 11. The optical functional layer 5 includes a touch control layer 51, a first refractive index layer 52, a second refractive index layer 53, and a polarizer 54 that are sequentially stacked from bottom to top. The refractive index of the first refractive index layer 52 is smaller than that of the second refractive index layer 53. The first refractive index layer 52 is provided with second openings 55. The second openings 55 and the light-emitting sub-pixels 11 are arranged in one-to-one correspondence. An orthogonal projection of the second opening 55 on the substrate 1 coincides with an orthogonal projection of the light-emitting sub-pixel 11 on the substrate 1. The first refractive index layer 52 and the second refractive index layer 53 at the second opening 55 constitute a microlens structure 12. Light rays emitted from the light-emitting sub-pixels 11 converge at the microlens structures 12. Further, the output amount of light from the positive viewing angle of the display panel is improved, and the light output efficiency of the display panel is improved.

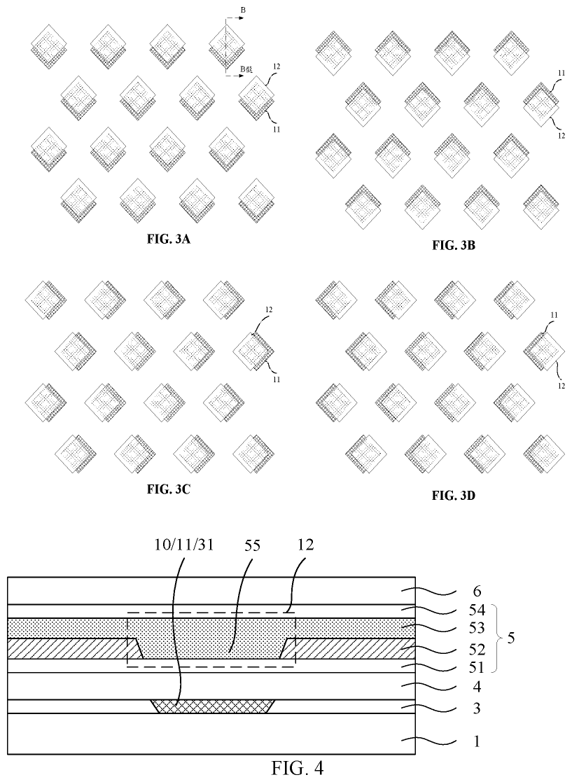

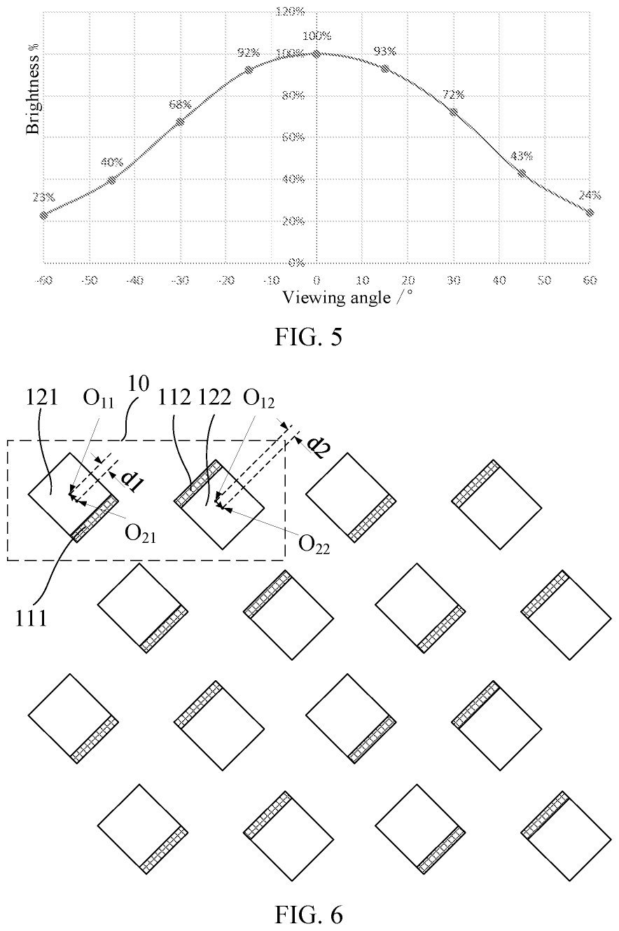

However, since the first refractive index layer 52 inevitably has a certain degree of alignment deviation during the manufacture process, there is a misalignment between the microlens structure 12 and the light-emitting sub-pixel. Referring to FIG. 3 and FIG. 4, FIG. 3 is a schematic view of plan structures of each of light-emitting sub-pixels with the same color and a corresponding one of microlens structures in a display panel in the prior art. Specifically, (a) of FIG. 3 is a schematic view of a plan structure of an upward alignment deviation in a manufacture process of microlens structures. (b) of FIG. 3 is a schematic view of a plan structure of a downward alignment deviation in a manufacture process of microlens structures. (c) of FIG. 3 is a schematic view of a plan structure of a leftward alignment deviation in a manufacture process of microlens structures. (d) of FIG. 3 is a schematic view of a plan structure of a rightward alignment deviation in a manufacture process of microlens structures. FIG. 4 is a schematic sectional view in the direction of BB′ in FIG. 3. It can be seen from FIG. 3 that, regardless of any one direction, all of the microlens structures 12 deviate in the same direction with respect to the respective light-emitting sub-pixels 11 when the alignment deviation occurs in the manufacture process of the first refractive index layer 52, which deteriorates the viewing angle symmetry of the display panel. Referring to FIG. 5, FIG. 5 is a view showing a result of viewing angle symmetry of a display panel in the prior art. As can be seen from FIG. 5, in the conventional display panel, the observed brightness of the display panel is different at symmetrical visual angles, and there is a problem of viewing angle symmetry.

In view of the above problems in the prior art, the present application provides a display panel which can solve or alleviate.

The present application provides a display panel including:
a substrate;
a light-emitting layer disposed on one side of the substrate, and the light-emitting layer including a plurality of light-emitting sub-pixels;
an optical functional layer disposed on a side of the light-emitting layer away from the substrate, the optical functional layer including a plurality of microlens structures arranged in one-to-one correspondence with the light-emitting sub-pixels;
in which the plurality of microlens structures includes a plurality of repeating units arranged periodically; the repeating units each includes a first microlens structure and a second microlens structure; the plurality of light-emitting sub-pixels include a first light-emitting sub-pixel corresponding to the first microlens structure and a second light-emitting sub-pixel corresponding to the second microlens structure;
there is a first interval in a first direction between a center point of the first microlens structure and a center point of the first light-emitting sub-pixel, there is a second interval in a second direction between a center point of the second microlens structure and a center point of the second light-emitting sub-pixel, and the first direction is different from the second direction.

According to the embodiment of the present application, each first microlens structure is set to be offset with respect to the center point of the corresponding first light-emitting sub-pixel, and each second microlens structure is set to be offset with respect to the center point of the corresponding second light-emitting sub-pixel. The two offset directions are different, so that the problem that all the microlens structures in the existing display panel are offset in one direction with respect to the respective light-emitting sub-pixels is alleviated to some extent, and the problem of viewing angle symmetry of the display panel is alleviated.

Hereinafter, a display panel provided in the present application will be explained in detail by using specific examples. Specifically, microlens structures of the display panel will be explained in detail. In the display panel, the light-emitting sub-pixels generally includes red light-emitting sub-pixels, green light-emitting sub-pixels, and blue light-emitting sub-pixels. For the light-emitting sub-pixels with any color, the microlens structures are provided in the same manner. For clarity of explanation, the light-emitting sub-pixels with the same color (taking blue light-emitting sub-pixels as an example) will be explained below.

### Example 1

Referring to FIG. 6, FIG. 6 is a first schematic diagram of a plane superposition structure of each of light-emitting sub-pixels with the same color and a corresponding one of microlens structures in a display panel according to an example of the present application. In the example of the present application, the shape of each microlens structure 12 is the same as the shape of the corresponding light emitting sub-pixel 11, and the size of the microlens structure 12 is the same as the size of the corresponding light emitting sub-pixel 11.

One repeating unit 10 includes two of the microlens structures 12, i.e., a first microlens structure 121 and a second microlens structure 122. The plurality of light-emitting sub-pixels 11 includes a first light-emitting sub-pixel 111 corresponding to the first microlens structure 121 and a second light-emitting sub-pixel 112 corresponding to the second microlens structure 122.

There is a first interval d1 in a first direction O₂₁O₁₁ between a center point O₂₁ of the first microlens structure 121 and a center point O₁₁ of the first light-emitting sub-pixel 111. There is a second interval d2 in a second direction O₂₂O₁₂ between a center point O₂₂ of the second microlens structure 122 and a center point O₁₂ of the second light-emitting sub-pixel 112. The first direction O₂₁O₁₁ is opposite to the second direction O₂₂O₁₂, and the first interval d1 and the second interval d2 are equal.

The first direction O₂₁O₁₁ shown in FIG. 6 is upper right, and the second direction O₂₂O₁₂ is lower left. In other examples of the present application, the first direction may be the lower right and the second direction may be the upper left, which is not limited.

In this way, the first microlens structure 121 is offset with respect to the first light-emitting sub-pixel 111 in the first direction O₂₁O₁₁ by the first interval d1. The light converging action of the first microlens structure 121 on the first light-emitting sub-pixel 111 is enhanced in the first direction O₂₁O₁₁ and attenuated in the second direction O₂₂O₁₂. The second microlens structure 122 is offset from the second light-emitting sub-pixel 112 in the second direction O₂₂O₁₂ by the second interval d2. The light converging action of the second microlens structure 122 on the second light-emitting sub-pixel 112 is enhanced in the second direction O₂₂O₁₂ and attenuated in the first direction O₂₁O₁₁.

Since the first interval d1 and the second interval d2 are equal, the light converging action of the first microlens structure 121 on the first light-emitting sub-pixel 111 is enhanced in the first direction O₂₁O₁₁, and the light converging action of the second microlens structure 122 on the second light-emitting sub-pixel 112 is enhanced in the second direction O₂₂O₁₂. The light converging action of the second microlens structure 122 on the second light emitting sub-pixel 112 in the first direction O₂₁O₁₁ has a same attenuated effect as the light converging action of the first microlens structure 121 on the first light emitting sub-pixel 111 in the second direction O₂₂O₁₂. Finally, the visual effects of the entire display panel in the first direction O₂₁O₁₁ and the second direction O₂₂O₁₂ are made the same, that is, the visual symmetry. In other directions, since each first microlens structure 121 and the corresponding first light-emitting sub-pixel 111 are overlapped with each other, and each second microlens structure 122 and the corresponding second light-emitting sub-pixel 112 are overlapped with each other, the display panel is visually symmetrical.

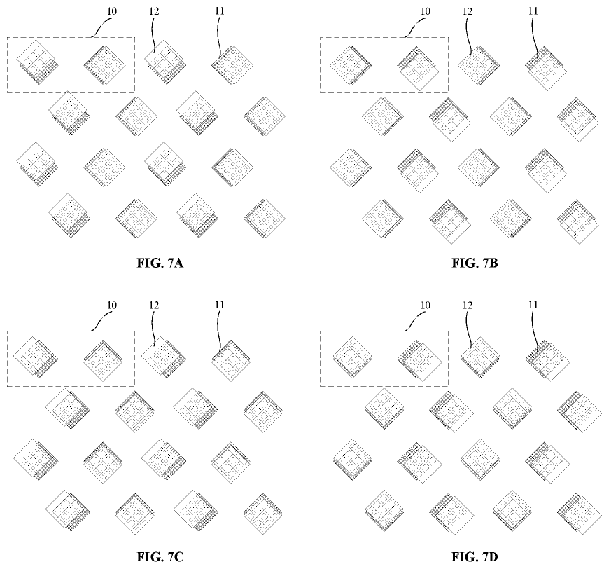

When the alignment deviation occurs in the manufacture process of the first refractive index layer 52, reference is made to FIG. 7, which is a plan diagram of a superposition structure of the microlens structures in FIG. 6 when occurring alignment deviation. Specifically, (a) of FIG. 7 is a schematic diagram of a plane superposition of microlens structures when occurring upward alignment deviation, (b) of FIG. 7 is a schematic diagram of a plane superposition structure of microlens structures when occurring downward alignment deviation, (c) of FIG. 7 is a schematic diagram of a plane superposition structure of microlens structures when occurring leftward alignment deviation, and (d) of FIG. 7 is a schematic diagram of a plane superposition structure of microlens structures when occurring rightward alignment deviation.

As shown in (a) of FIG. 7, when upward alignment deviation occurs in a process of manufacturing the first refractive index layer 52, there is a microlens structure 12 in one of the repeating units 10, and a center point of this microlens structure 12 is on the same horizontal line as a center point of the corresponding light-emitting sub-pixel 11. That is, the light converging actions of the microlens structure 12 on the light-emitting sub-pixel 11 are symmetrical in the up-down direction, thereby improving the viewing angle symmetry of the display panel in the up-down direction by 50%.

As shown in (b) of FIG. 7, when downward alignment deviation occurs in a process of manufacturing the first refractive index layer 52, there is a microlens structure 12 in one of the repeating units 10, and a center point of this microlens structure 12 is on the same horizontal line as a center point of the corresponding light-emitting sub-pixel 11. That is, the light converging actions of microlens structure 12 on the light-emitting sub-pixel 11 are symmetrical in the up-down direction, thereby improving the viewing angle symmetry of the display panel in the up-down direction by 50%.

As shown in (c) of FIG. 7, when leftward alignment deviation occurs in a process of manufacturing the first refractive index layer 52, there is a microlens structure 12 in one of the repeating units 10, and a center point of this microlens structure 12 is on the same perpendicular line as a center point of the corresponding light-emitting sub-pixel 11. That is, the light converging actions of the microlens structure 12 on the light-emitting sub-pixel 11 are symmetrical in the left-right direction, thereby improving the viewing angle symmetry of the display panel in the left-right direction by 50%.

As shown in (d) of FIG. 7, when rightward alignment deviation occurs in a process of manufacturing the first refractive index layer 52, there is a microlens structure 12 in one of the repeating units 10, and a center point of this microlens structure 12 is on the same perpendicular line as a center point of the corresponding light-emitting sub-pixel 11. That is, the light converging actions of the microlens structure 12 on the light-emitting sub-pixel 11 are symmetrical in the left-right direction, thereby improving the viewing angle symmetry of the display panel in the left and right directions by 50%.

The light-emitting sub-pixels of the display panel include red light-emitting sub-pixels, green light-emitting sub-pixels, and blue light-emitting sub-pixels. Further, the light-emitting sub-pixels may further include white light-emitting sub-pixels. The arrangement of the microlens structures corresponding to the red light-emitting sub-pixels, the green light-emitting sub-pixels, and the blue light-emitting sub-pixels is the same as that of the above microlens structures 12.

In one embodiment, the first interval between each red light-emitting sub-pixel and a corresponding microlens structure, the first interval between each green light-emitting sub-pixel and a corresponding microlens structure, the first interval between each blue light-emitting sub-pixel and a corresponding microlens structure are all equal, and the first interval is less than or equal to 4 microns. When the alignment deviation occurs, the first interval and the second interval after the offset are less than or equal to 5 microns.

In another embodiment, the first interval between each red light-emitting sub-pixel and a corresponding microlens structure is greater than the first interval between each green light-emitting sub-pixel and a corresponding microlens structure and less than the first interval between each blue light-emitting sub-pixel and a corresponding microlens structure. Specifically, the first interval between the red light-emitting sub-pixel and the corresponding microlens structure is greater than 1 micron and less than or equal to 2 microns, the first interval between the green light-emitting sub-pixel and the corresponding microlens structure is less than or equal to 1 micron, and the first interval between the blue light-emitting sub-pixel and the corresponding microlens structure is greater than or equal to 2 microns and less than or equal to 4 microns. The first interval between the red light-emitting sub-pixel and the corresponding microlens structure after the offset is greater than 0 and less than or equal to 3 microns, the first interval between the green light-emitting sub-pixel and the corresponding microlens structure is less than or equal to 2 microns, and the first interval between the blue light-emitting sub-pixel and the corresponding microlens structure is greater than or equal to 1 micron and less than or equal to 5 microns.

On the basis of the present example, the repeating unit may further include one or more third microlens structures, the light emitting sub-pixel includes a third light emitting sub-pixel corresponding to the third microlens structure. A center point of the third microlens structure coincides with a center point of the third light emitting sub-pixel.

### Example 2

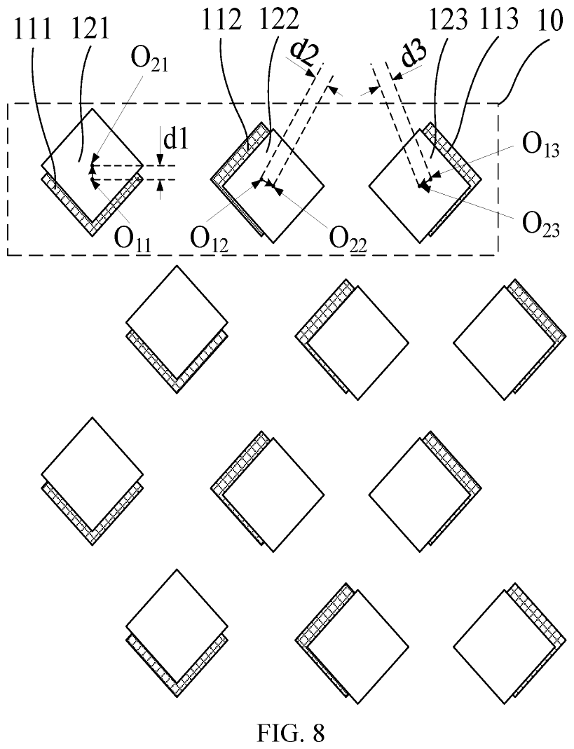

Referring to FIG. 8, FIG. 8 is a second schematic diagram of a plane superposition structure of each of sub-pixels with the same color and a corresponding one of microlens structures in a display panel according to an example of the present application. The parts of the present example similar to the Example 1 are not described in detail, and reference is made to the Example 1 for details. The present example differs from the Example 1 in that a repeating unit 10 includes three microlens structures 12, i.e., a first microlens structure 121, a second microlens structure 122, and a third microlens structure 123. The plurality of light-emitting sub-pixels 11 includes a first light-emitting sub-pixel 111 corresponding to the first microlens structure 121, a second light-emitting sub-pixel 112 corresponding to the second microlens structure 122, and a third light-emitting sub-pixel 113 corresponding to the third microlens structure 123.

There is a first interval d1 in a first direction O₂₁O₁₁ between a center point O₂₁ of the first microlens structure 121 and a center point O₁₁ of the first light-emitting sub-pixel 111. There is a second interval d2 in a second direction O₂₂O₁₂ between a center point O₂₂ of the second microlens structure 122 and a center point O₁₂ of the second light-emitting sub-pixel 112. There is a third interval d3 in a third direction O₂₃O₁₃ between a center point O₂₃ of the third microlens structure 123 and a center point O₁₃ of the third light-emitting sub-pixel 113. The first direction O₂₁O₁₁, the second direction O₂₂O₁₂, and the third direction O₂₃O₁₃ are sequentially spaced 120 degrees apart. The first interval d1, the second interval d2, and the third interval d3 are all equal.

The first direction O₂₁O₁₁ shown in FIG. 8 is directly right, the second direction O₂₂O₁₂ is lower right, and the third direction O₂₃O₁₃ is lower left. In other embodiments of the present application, other orientation settings may be used, and are not limited herein.

Similarly, since the first direction O₂₁O₁₁, the second direction O₂₂O₁₂, and the third direction O₂₃O₁₃ are sequentially spaced 120 degrees apart, and the first interval d1, the second interval d2, and the third interval d3 are all equal, the three microlens structures 12 in the repeating unit 10 have a comprehensive effect on the respective three photon-emitting pixels 11, so that the visual effects of the display panel in any two opposite directions are symmetrical. For a specific principle, reference is made to Example 1.

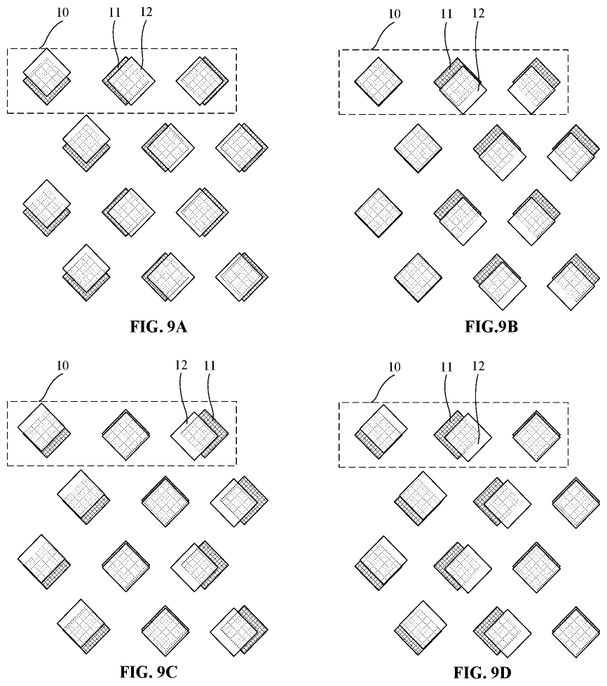

When the alignment deviation occurs in the manufacture of the first refractive index layer 52, reference is made to FIG. 9, which is a diagram of a plan superposition structure of the microlens structures in FIG. 8 when occurring alignment deviation.

As shown in (a) of FIG. 9, (a) of FIG. 9 is a schematic diagram of a plane superposition structure of the microlens structures when occurring upward alignment deviation. When upward alignment deviation occurs in the manufacture of the first refractive index layer 52, in one of the repeating units 10, there are two microlens structures 12 whose center points are each on the same horizontal line as a center point of a corresponding light-emitting sub-pixel 11. That is, the light converging actions of each of the two microlens structure 12 on the respective light-emitting sub-pixel 11 are symmetrical in the up-down direction, thereby improving the viewing angle symmetry of the display panel in the up-down direction by 67%.

As shown in (b) of FIG. 9, (b) of FIG. 9 is a schematic diagram of a plane superposition structure of microlens structures when occurring downward alignment deviation. When a downward alignment deviation occurs in the manufacture of the first refractive index layer 52, in one of the repeating units 10, there is a microlens structure 12 whose center point coincides with a center point of the corresponding light-emitting sub-pixel 11. That is, light converging actions of the microlens structure 12 on the light-emitting sub-pixel 11 are symmetrical in the up-down direction, thereby improving the viewing angle symmetry of the display panel in the up-down direction by 33%.

As shown in (c) of FIG. 9, (c) of FIG. 9 is a schematic diagram of a plane superposition structure of the microlens structures when occurring leftward alignment deviation. When leftward alignment deviation occurs in the manufacture of the first refractive index layer 52, in one of the repeating units 10, there is a microlens structure 12 whose center point is on the same perpendicular line as a center point of the corresponding light-emitting sub-pixel 11. That is, the light converging actions of the microlens structure 12 on the light-emitting sub-pixel 11 are symmetrical in the left-right direction, thereby improving the viewing angle symmetry of the display panel in the left and right directions by 33%.

As shown in (d) of FIG. 9, (d) of FIG. 9 is a schematic diagram of a plane superposition structure of the microlens structures when occurring rightward alignment deviation. When the rightward alignment deviation occurs in a manufacture of the first refractive index layer 52, in one of the repeating units 10, there is a microlens structure 12 whose center point is on the same perpendicular line as the center point of the corresponding light-emitting sub-pixel 11. That is, the light converging actions of the microlens structure 12 on the light-emitting sub-pixel 11 are symmetrical in the left-right direction, thereby improving the viewing angle symmetry of the display panel in the left and right directions by 33%.

### Example 3

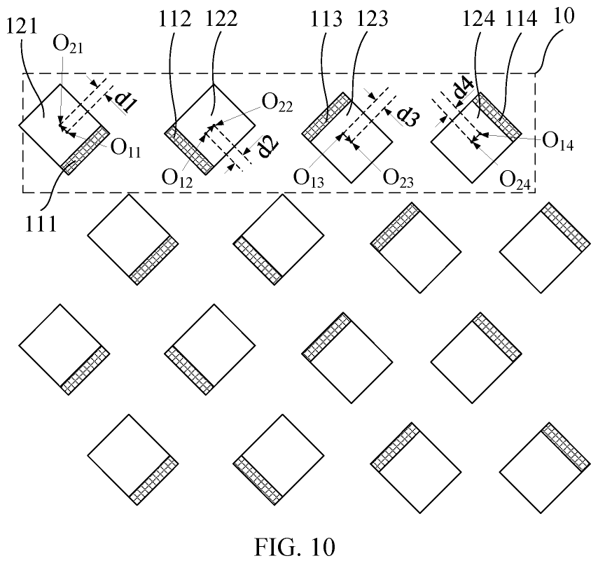

Referring to FIG. 10, FIG. 10 is a third schematic diagram of a plane superposition structure of each of light-emitting sub-pixels with the same color and a corresponding one of microlens structures in a display panel according to an example of the present application. The parts of the present example similar to the Example 1 are not described in detail, and reference is made to the Example 1 for details. The present embodiment differs from the Example 1 in that a repeating unit 10 includes four microlens structures 12, i.e., a first microlens structure 121, a second microlens structure 122, a third microlens structure 123, and a fourth microlens structure 124. The plurality of light-emitting sub-pixels 11 includes a first light-emitting sub-pixel 111 corresponding to the first microlens structure 121, a second light-emitting sub-pixel 112 corresponding to the second microlens structure 122, a third light-emitting sub-pixel 113 corresponding to the third microlens structure 123, and a fourth light-emitting sub-pixel 114 corresponding to the fourth microlens structure 124.

There is a first interval d1 in a first direction O₂₁O₁₁ between a center point O₂₁ of the first microlens structure 121 and a center point O₁₁ of the first light-emitting sub-pixel 111. There is a second interval d2 in a second direction O₂₂O₁₂ between a center point O₂₂ of the second microlens structure 122 and a center point O₁₂ of the second light-emitting sub-pixel 112. There is a third interval d3 in a third direction O₂₃O₁₃ between a center point O₂₃ of the third microlens structure 123 and the center point O₁₃ of the third light-emitting sub-pixel 113. There is a fourth interval d4 in a fourth direction O₂₄O₁₄ between a center point O₂₄ of the fourth microlens structure 124 and a center point O₁₄ of the fourth light-emitting sub-pixel 114. The first direction O₂₁O₁₁, the second direction O₂₂O₁₂, the third direction O₂₃O₁₃, and the fourth direction O₂₄O₁₄ are sequentially spaced 90 degrees apart. The first interval d1, the second interval d2, the third interval d3, and the fourth interval d4 are all equal.

The first direction O₂₁O₁₁ shown in FIG. 10 is directly left, the second direction O₂₂O₁₂ is upper right, the third direction O₂₃O₁₃ is lower right, and the fourth direction O₂₄O₁₄ is lower left. In other embodiments of the present application, other orientation settings may be used, and are not limited herein.

Similarly, since the first direction O₂₁O₁₁, the second direction O₂₂O₁₂, the third direction O₂₃O₁₃, and the fourth direction O₂₄O₁₄ are sequentially spaced by 90 degrees, and the first interval d1, the second interval d2, and the fourth interval d4 are all equal, the four microlens structures 12 in the repeating unit 10 have a comprehensive effect on the respective four photon-emitting pixels 11, so that the visual effects of the display panel in any two opposite directions are symmetrical. For a specific principle, reference is made to Example 1.

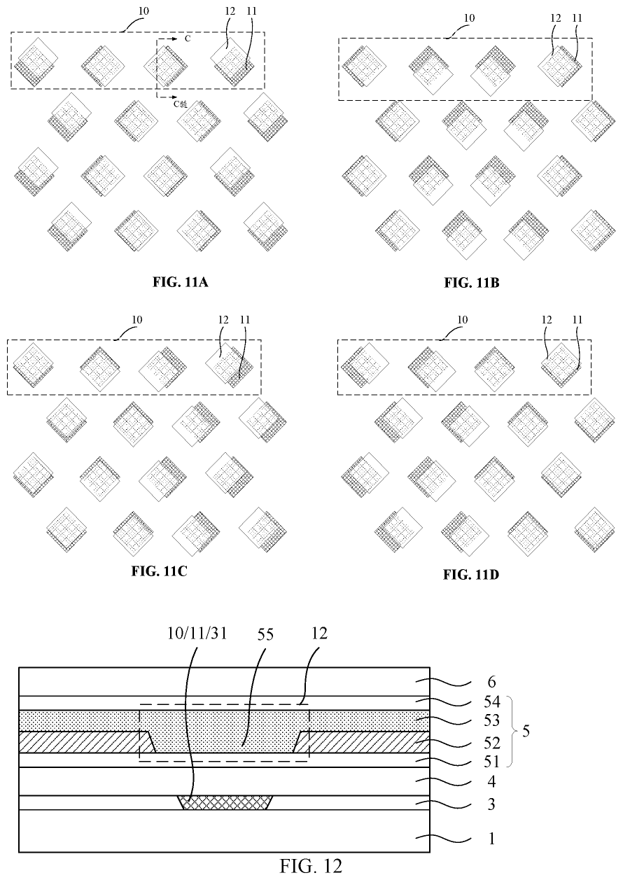

When the alignment deviation occurs in the manufacture of the first refractive index layer 52, reference is made to FIG. 11, which is a diagram of a plan superposition structure of the microlens structures in FIG. 10 when the alignment deviation occurs.

As shown in (a) of FIG. 11, (a) of FIG. 11 is a schematic diagram of a plan superposition of microlens structures when occurring upward alignment deviation. When upward alignment deviation occurs in the manufacture of the first refractive index layer 52, in one of the repeating units 10, there are two microlens structures 12 whose center points are each on the same horizontal line as the center point of the respective light-emitting sub-pixel 11. That is, the light converging actions of each of the two microlens structure 12 on the corresponding light-emitting sub-pixel 11 are symmetrical in the up-down direction, so that the viewing angle symmetry of the display panel in the up-down-direction—is improved by 50%.

As shown in (b) of FIG. 11, (b) of FIG. 11 is a schematic diagram of a plane superposition structure of microlens structures when occurring downward alignment deviation. When a downward alignment deviation occurs in a manufacture of the first refractive index layer 52, there are two microlens structures 12 in one of the repeating units 10, whose center points are each on the same horizontal line as the center point of the respective light-emitting sub-pixel 11. That is, the light converging actions of each of the two microlens structures 12 on the respective light-emitting sub-pixel 11 are symmetrical in the up-down direction, thereby improving the viewing angle symmetry of the display panel in the upper and lower directions by 50%.

As shown in (c) of FIG. 11, (c) of FIG. 11 is a schematic diagram of a plane superposition structure of microlens structures when occurring leftward alignment deviation. When a leftward alignment deviation is occurred in the manufacture of the first refractive index layer 52, there are two microlens structures 12 in one repeating unit 10, whose center points are each on the same vertical line as the center point of the respective light-emitting sub-pixel 11. That is, the light converging actions of each of the two microlens structures 12 on the respective light-emitting sub-pixel 11 are symmetrical in the left-right direction, thereby improving the viewing angle symmetry of the display panel in the left and right directions by 50%.

As shown in (d) of FIG. 11, (d) of FIG. 11 is a schematic diagram of a plane superposition structure of the microlens structures when occurring rightward alignment deviation. When a rightward alignment deviation occurs in the manufacture of the first refractive index layer 52, in one of the repeating units 10, there are two microlens structures 12 whose center points are each on the same perpendicular line as the center point of the respective light-emitting sub-pixel 11. That is, the light converging actions of each of the two microlens structures 12 on the respective light-emitting sub-pixel 11 are symmetrical in the left-right direction, thereby improving the viewing angle symmetry of the display panel in the left-right direction by 50%.

On the basis of Examples 1 to 3, with expanding to other examples, the repeating unit 10 may further include five or more of the microlens structures 12. The interval between the center points of any two adjacent microlens structures 12 with respect to the offset direction of the center points of the respective light-emitting sub-pixels 11 is equal, and the interval between the center points is equal.

### Example 4

Referring to FIG. 12, FIG. 12 is a fourth schematic diagram of a plane superposition structure of each of light-emitting sub-pixels with the same color and a corresponding one of microlens structures in a display panel according to an example of the present application. In the example of the present application, the shape of the microlens structure 12 is the same as that of the corresponding light emitting sub-pixel 11, the size of the microlens structure 12 is larger than that of the corresponding light emitting sub-pixel 11, and the orthographic projection of the microlens structure 12 on the substrate 1 covers the orthographic projection of the corresponding light emitting sub-pixel 11 on the substrate 1.

One repeating unit 10 includes two of the microlens structures 12, i.e., a first microlens structure 121 and a second microlens structure 122. The plurality of light-emitting sub-pixels 11 includes a first light-emitting sub-pixel 111 corresponding to the first microlens structure 121 and a second light-emitting sub-pixel 112 corresponding to the second microlens structure 122.

There is a first interval d1 in a first direction O₂₁O₁₁ between a center point O₂₁ of the first microlens structure 121 and a center point O₁₁ of the first light-emitting sub-pixel 111. The size of the first microlens structure 121 in the other direction is the same as the size of the first light-emitting sub-pixel 111, and the size of the first microlens structure 121 in the first direction O₂₁O₁₁ is extended in a direction of one side. There is a second interval d2 in a second direction O₂₂O₁₂ between a center point O₂₂ of the second microlens structure 122 and a center point O₁₂ of the second light emitting sub-pixel 112. The size of the second microlens structure 122 in the other direction is the same as the size of the second light emitting sub-pixel 112, and the size of the second microlens structure 122 in the second direction O₂₂O₁₂ is extended in a direction of one side. The first direction O₂₁O₁₁ is opposite to the second direction O₂₂O₁₂, and the first interval d1 and the second interval d2 are equal.

Similarly, since the first direction O₂₁O₁₁ and the second direction O₂₂O₁₂ are opposite, and the first interval d1 and the second interval d2 are equal, the two microlens structures 12 in one of the repeating units 10 have a comprehensive effect on the respective two light-emitting sub-pixels 11. So, the visual effects of the display panel in any two opposite directions are symmetrical. For a specific principle, reference is made to Example 1.

In one embodiment, the first interval between each red light-emitting sub-pixel and a corresponding microlens structure, the first interval between each green light-emitting sub-pixel and a corresponding microlens structure, the first interval between each blue light-emitting sub-pixel and a corresponding microlens structure are all equal, and the first interval is less than or equal to 4 microns.

In another embodiment, the first interval between each red light-emitting sub-pixel and a corresponding microlens structure is greater than the first interval between each green light-emitting sub-pixel and a corresponding microlens structure and less than the first interval between each blue light-emitting sub-pixel and a corresponding microlens structure. Specifically, the first interval between the red light-emitting sub-pixel and the corresponding microlens structure is greater than 1 micron and less than or equal to 2 microns, the first interval between the green light-emitting sub-pixel and the corresponding microlens structure is less than or equal to 1 micron, and the first interval between the blue-light-emitting sub-pixel and the corresponding microlens structure is greater than or equal to 2 microns and less than or equal to 4 microns.

In other embodiments, the repeating unit 10 may further include three, four, five, or even more of the microlens structures 12. The interval between the center points of any two adjacent microlens structures 12 is equal with respect to the offset direction of the center points of the respective light-emitting sub-pixels 11, and the interval between the center points is equal. In other embodiments, the microlens structure 12 may be single-sided extended with respect to the corresponding light-emitting sub-pixel 11, or may be double-sided or even multi-variable extended.

Correspondingly, an embodiment of the present application provides a display panel. Referring to FIG. 12, FIG. 12 is a schematic cross-sectional structure of the display panel provided in the present application. Specifically, a schematic cross-sectional structure in a direction of CC′ in FIG. 11. A substrate 1, a light-emitting layer 2, a pixel definition layer 3, an encapsulation layer 4, an optical functional layer 5, and a cover plate 6 are stacked in sequence. The light-emitting layer 2 includes a plurality of light-emitting sub-pixels 11, and the pixel definition layer 3 is disposed between the substrate 1 and the light-emitting layer 2. The pixel definition layer 3 includes a plurality of first openings 31 corresponding to the light-emitting sub-pixels. The optical functional layer 5 includes a touch control layer 51, a first refractive index layer 52, a second refractive index layer 53, and a polarizer 54 stacked in sequence from bottom to top. The first refractive index layer 52 has a refractive index smaller than that of the second refractive index layer 53. The first refractive index layer 52 is provided with second openings 55. The second opening 55 and the light-emitting sub-pixels 11 are arranged in one-to-one correspondence. The orthogonal projection of the second opening 55 on the substrate 1 coincides with the orthogonal projection portion of the first opening 31 on the substrate 1, and the first refractive index layer 52 and the second refractive index layer 53 at the second opening 55 constitute a microlens structure 12.

An embodiment of the present application further provides a display device including the display panel according to any one of the embodiments of the present application.

In summary, embodiments of the present application provide a display panel and a display device. Each first microlens structure of the display panel is set to be offset with respect to a center point of a corresponding first light-emitting sub-pixel, and each second microlens structure is set to be offset with respect to a center point of a corresponding second sub-light-emitting pixel. Two offset directions are different. In this way, a problem that all the microlens structures in an existing display panel are offset in one direction with respect to respective light-emitting sub-pixels is alleviated, thereby alleviating a problem of viewing angle symmetry of the display panel.

The present application has been described in detail with reference to a display panel and a display device according to an embodiment of the present invention. The principles and embodiments of the present application have been described with reference to specific examples. The description of the above embodiments is merely provided to help understand the method of the present application and the core idea thereof. At the same time, variations will occur to those skilled in the art in both the detailed description and the scope of application in accordance with the teachings of the present application. In view of the foregoing, the present description should not be construed as limiting the application.

1. A display panel comprising:
a substrate;
a light-emitting layer disposed on one side of the substrate, the light-emitting layer comprising a plurality of light-emitting sub-pixels;
an optical functional layer disposed on a side of the light-emitting layer away from the substrate, the optical functional layer comprising a plurality of microlens structures that are arranged in one-to-one correspondence with the light-emitting sub-pixels;
wherein the plurality of microlens structures comprise a plurality of repeating units arranged periodically; each of the repeating units comprises a first microlens structure and a second microlens structure; the plurality of light-emitting sub-pixels comprise a first light-emitting sub-pixel corresponding to the first microlens structure and a second light-emitting sub-pixel corresponding to the second microlens structure;
there is a first interval in a first direction is between a center point of the first microlens structure and a center point of the first light-emitting sub-pixel, there is a second interval in a second direction between the center point of the second microlens structure and a center point of the second light-emitting sub-pixel, and the first direction is different from the second direction.

2. The display panel according to claim 1, wherein the first direction is opposite to the second direction;
the first interval and the second interval are the same.

3. The display panel according to claim 1, wherein each of the repeating units further comprises a third microlens structure; the plurality of light-emitting sub-pixels further comprise a third light-emitting sub-pixel corresponding to the third microlens structure;
there is a third interval in a third direction between a center point of the third microlens structure and a center point of the third light-emitting sub-pixel, and the first direction, the second direction, and the third direction are different.

4. The display panel according to claim 3, wherein the first direction, the second direction, and the third direction are arranged at intervals of 120 degrees in sequence;
the first interval, the second interval, and the third interval are the same.

5. The display panel according to claim 3, wherein each of the repeating units further comprises a fourth microlens structure; the plurality of light-emitting sub-pixels further comprise a fourth light-emitting sub-pixel corresponding to the fourth microlens structure;
there is a fourth interval in a fourth direction between a center point of the fourth microlens structure and a center point of the fourth light-emitting sub-pixel, and the first direction, the second direction, the third direction, and the fourth direction are different.

6. The display panel according to claim 5, wherein the first direction, the second direction, the third direction, and the fourth direction are arranged at intervals of 90 degrees in sequence;
the first interval, the second interval, the third interval, and the fourth interval are the same.

7. The display panel according to claim 1, wherein each of the microlens structures has a same shape as a corresponding one of the light-emitting sub-pixels, and the microlens structure has a same size as the corresponding one of the light-emitting sub-pixels.

8. The display panel according to claim 7, wherein the first interval and the second interval are less than or equal to 5 microns.

9. The display panel according to claim 8, wherein the plurality of light-emitting sub-pixels comprise a plurality of red light-emitting sub-pixels, a plurality of green light-emitting sub-pixels, and a plurality of blue light-emitting sub-pixels; and the first interval corresponding to any one of the red light-emitting sub-pixels, the first interval corresponding to any one of the green light-emitting sub-pixels, and the first interval corresponding to any one of the blue light-emitting sub-pixels are equal to each other.

10. The display panel according to claim 8, wherein the plurality of the light-emitting sub-pixels comprise red light-emitting sub-pixels, green light-emitting sub-pixels, and blue light-emitting sub-pixels; the first interval corresponding to any one of the red light-emitting sub-pixels is smaller than the first interval corresponding to any one of the green light-emitting sub-pixels and larger than the first interval corresponding to any one of the blue light-emitting sub-pixels.

11. The display panel according to claim 10, wherein the first interval corresponding to any one of the red light-emitting sub-pixel is greater than 1 micron and less than or equal to 3 microns, the first interval corresponding to any one of the blue light-emitting sub-pixels is greater than 0 microns and less than or equal to 2 microns, and the first interval corresponding to any one of the green light-emitting sub-pixels is greater than 2 microns and less than or equal to 5 microns.

12. The display panel according to claim 1, wherein the microlens structures each have a same shape as a corresponding one of the light-emitting sub-pixels, and a size of the microlens structure is greater than a size of the corresponding one of the light-emitting sub-pixels.

13. The display panel according to claim 1, wherein the display panel further comprises:
a pixel definition layer disposed between the substrate and the light-emitting layer, and the pixel definition layer comprises a plurality of first openings corresponding to the light-emitting sub-pixels;
the optical functional layer comprises a first refractive index layer disposed on a side of the light-emitting layer which is away from the substrate, and a second refractive index layer disposed on a side of the first refractive index layer which is away from the substrate, the first refractive index layer comprises a plurality of second openings corresponding to the microlens structures, and a refractive index of the first refractive index layer is smaller than a refractive index of the second refractive index layer.

14. A display device comprising the display panel according to claim 1.

15. The display device according to claim 14, wherein the first direction is opposite to the second direction;
the first interval and the second interval are the same.

16. The display device according to claim 14, wherein the repeating units each further comprise a third microlens structure; the plurality of light-emitting sub-pixels further comprise a third light-emitting sub-pixel corresponding to the third microlens structure;
there is a third interval in a third direction between a center point of the third microlens structure and a center point of the third light-emitting sub-pixel, and the first direction, the second direction, and the third direction are different.

17. The display device according to claim 16, wherein the first direction, the second direction, and the third direction are arranged at intervals of 120 degrees in sequence;
the first interval, the second interval, and the third interval are the same.

18. The display device according to claim 16, wherein the repeating units each further comprise a fourth microlens structure; the plurality of light-emitting sub-pixels further include a fourth light-emitting sub-pixel corresponding to the fourth microlens structure;
there is a fourth interval in a fourth direction between a center point of the fourth microlens structure and a center point of the fourth light-emitting sub-pixel, and the first direction, the second direction, the third direction, and the fourth direction are different.

19. The display device according to claim 18, wherein the first direction, the second direction, the third direction, and the fourth direction are arranged at intervals of 90 degrees in sequence;
the first interval, the second interval, the third interval, and the fourth interval are the same.

20. The display device according to claim 14, wherein the microlens structures each have a same shape as a corresponding one of the light-emitting sub-pixels, and the microlens structure has a same size as the corresponding one of the light-emitting sub-pixels.
